(19) United States
(12) Patent Application Publication
(10) Pub. No.: US 2007/0215036 A1
(43) Pub. Date: Sep. 20, 2007

(54) Method and apparatus of time and space co-divided atomic layer deposition

(76) Inventors: Hyung-Sang Park, Seoul (KR); Young-Duck Tak, Daejeon (KR); Wonyong Koh, Tokyo (JP); Akira Shimizu, Sagamihara-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/376,817

(22) Filed: Mar. 15, 2006

(51) Int. Cl. C30B 23/00; C23C 16/00

(52) U.S. Cl. 117/88; 427/248.1; 118/715; 118/716

(57) ABSTRACT

Space and time co-divided atomic layer deposition (ALD) apparatuses and methods are provided. Substrates are moved (e.g., rotated) among multiple reaction zones, each of which is exposed to only one ALD reactant. At the same time, reactants are pulsed in each reaction zone, with purging or other gas removal methods between pulses. Separate exhaust passages for each reactant and purging during wafer movement minimizes particle contamination. Additionally, preferred embodiments permit different pulsing times in each reaction space, thus permitting flexibility in pulsing.

### BACKGROUND OF THE INVENTION

1. Field of the Invention

The invention generally relates to semiconductor processing and, more particularly, to atomic layer deposition (ALD) apparatuses and methods.

2. Description of the Related Art

As semiconductor integration technologies advance, process methods for depositing a thin film uniformly and conformally become increasingly important. Here, the thin film may be an insulator or a conductor. Thin film deposition methods are largely categorized into three types: chemical vapor deposition (CVD), physical vapor deposition (PVD) and atomic layer deposition (ALD), sometimes called atomic layer epitaxy (ALE).

In CVD, gas phase materials generally react on the top surface of a substrate heated to a temperature between about 100° C. to 1,000° C., whereby a solid material produced as a result of such reaction is deposited on the top surface of the substrate. In PVD, films are typically deposited onto a substrate surface via evaporation or via ion-assisted sputtering from a target material.

As the density of semiconductor devices continues to increase, device feature sizes decrease, necessitating methods to form substantially thin and uniform features. Unfortunately, conventional CVD and PVD methods do not perform satisfactorily in forming uniform thin films over substrates including high aspect-ratio features, such as vias and trenches. ALD, on the other hand, has shown promise in meeting the demands for thin and substantially uniform films, and also shows superior control over film properties such as composition.

ALD is a self-limiting process, whereby sequential and alternating pulses of reaction precursors saturate a substrate surface and typically leave no more than about one monolayer of material per pulse. The deposition conditions and precursors are selected to ensure self-saturating (or self-limiting) reactions, such that an adsorbed layer in one pulse leaves a surface termination that is non-reactive with the gas phase reactants of the same pulse. A subsequent pulse of different species (or reactants) reacts with the previous termination to enable continued deposition. Thus, each cycle of alternated pulses leaves no more than about one monolayer of the desired material. The principles of ALD have been presented by T. Suntola in, e.g. the Handbook of Crystal Growth 3, Thin Films and Epitaxy, Part B: Growth Mechanisms and Dynamics, Chapter 14, Atomic Layer Epitaxy, pp. 601-663, Elsevier Science B.V. 1994, the disclosure of which is incorporated herein by reference. As will be appreciated by the skilled artisan, some ALD recipes employ separated pulses of three or more reactants; some reactants leave desired elements in the growing film while some merely prepare or treat the surface for subsequent reactions such as stripping of one or more ligands.

Typically in ALD, raw materials comprising, e.g., two or more vapor phase reactants are alternately and sequentially directed into a reaction space. In a simple example, the reactants will be referred to herein as “S” for “source” of adsorbed species and “R” for “reactant” that reacts with the adsorbed species. S and R are mutually reactive and are preferably not present in the reaction space at the same time. The first reactant (S) is contacted with a substrate surface to adsorb at most one monolayer of a thin film of largely intact species S or fragments thereof. Typically, S includes ligands on tails that self-terminate the adsorption. Remaining gas phase reactant S is removed from the reaction space before the introduction of a second reactant (R). Removal may entail, e.g., directing a purge gas (“P”) into the reaction space or pumping the reaction space using a vacuum generated by a pumping system. The monolayer left by reactant S is subsequently contacted with reactant R to form at most one monolayer of a thin film. It will be understood that the binary reactions described herein are exemplary only and many variations of ALD exist. For example, the cycles need not start with the adsorbed species; the reactant R can contribute elements in the growing film; R can merely strip ligands from the adsorbed species; multiple different adsorbing reactants can be provided in separate pulses in each cycle; identical cycles can be repeated or cycles can be altered during the deposition process; etc.

ALD may be performed in single-wafer reactors, such as, e.g., the reactor disclosed by U.S. Pat. No. 6,812,157 to Gadgil, filed Nov. 2, 2004. The self-limiting nature of ALD makes its application in high-throughput operations difficult since formation of films or thin films one monolayer (typically less, due to steric hindrance) at a time can be time consuming. Additionally, because reactor parts of a single-wafer ALD apparatus are exposed to the same reactants, problems (e.g., blockage, contamination) associated with particle generation can arise, which may lead to significant down-time.

Multi-wafer systems, on the other hand, have the potential for meeting the demands of the semiconductor industry. In multi-wafer ALD systems, two basic techniques are typically employed in separating reactive gases. These are referred to herein as “the space separation method” and “the time separation method”. Pulsing sequences for these two methods are shown in FIGS. 1A and 1B, respectively.

With reference to FIG. 1A, wherein time and space are represented by the azimuth and ordinate, in the space separation method, the substrate is physically moved from one reaction space (or environment, zone), where reactant S is present, to another chemically decoupled environment, where reactant R is present. In a typical space separation method, wafers are rotated among reaction spaces (each dedicated to one reactant or a purge gas) on a rotary platform. Thus, every pulse typically divides equally in a cycle, i.e., pulse durations are the same in each reaction space. An ALD/CVD reactor employing a rotary space separation method is disclosed in U.S. Pat. Nos. 5,366,555, filed Nov. 22, 1994, and 6,869,641 to Schmitt (“Schmitt”), filed Mar. 22, 2005, the entire disclosure of which is incorporated herein by reference. In Schmitt, the pulsing time in each chamber may not be necessarily the same, however, still is fixed; it is determined by the angular velocity of a rotary turntable that a plurality of substrates rest upon.

With reference to FIG. 1B, in the time separation method, the substrate remains in one chamber (which may hold one or a plurality of substrates) and is exposed in successive independent steps to reactants S and R. In-between exposure to the reactive gases S and R, the substrate environment is evacuated by, e.g., purging (P) with a non-reactive gas, such as argon. An ALD system employing the time separation method is disclosed in U.S. Pat. No. 6,539,891, filed Apr. 1, 2003, the entire disclosure of which is incorporated herein by reference.

### SUMMARY OF THE INVENTION

In one embodiment of the invention, methods of forming a film or thin film over a substrate using an atomic layer deposition (ALD) apparatus comprise providing a substrate with a surface exposed to a first reaction space; contacting the surface with a vapor phase pulse of a first reactant in the first reaction space; removing the first reactant from the first reaction space; moving the substrate away from the first reaction space and towards a second reaction space; exposing the surface of the substrate to the second reaction space; and contacting the surface with a vapor phase pulse of a second reactant in the second reaction space. In some embodiments, providing the substrate comprises forming a seal between a portion of the surface of the substrate and a lower portion of an enclosure that defines the first reaction space. In other embodiments, providing the substrate comprises forming a seal between a substrate support platform and the lower portion of the enclosure, such that a portion of the substrate support platform is exposed to the first reaction space.

In another embodiment of the invention, methods for processing a plurality of wafers using a semi-batch deposition apparatus, the semi-batch deposition apparatus including a plurality of chambers, comprise the steps of: (a) introducing a surface of a first wafer to a first chamber and a surface of a second wafer to a second chamber; (b) pulsing a first vapor phase reactant into the first chamber for a first time period and a second vapor phase reactant into the second chamber for a second time period; (c) removing the first vapor phase reactant from the first chamber after the first time period and the second vapor phase reactant from the second chamber after the second time period; (d) moving the first wafer away from the first chamber and the second wafer away from the second chamber; (e) moving the first wafer towards the second chamber to introduce the surface of the first wafer to the second chamber; and (f) pulsing the second vapor phase reactant into the second chamber for a third time period. In some embodiments, the third time period is equivalent to the second time period. In other embodiments, the third time period is not equivalent to the second time period.

In yet another embodiment of the invention, methods for processing a wafer using a deposition apparatus comprise providing a plurality of spatially-separated reaction zones including a first reaction zone and a second reaction zone; repeatedly moving a wafer between the first reaction zone and the second reaction zone; repeatedly and alternately pulsing and removing a first reactant vapor in the first reaction zone; and repeatedly and alternately pulsing and removing a second reactant in the second reaction zone.

In yet another embodiment of the invention, vapor phase deposition apparatuses are provided. The apparatuses comprise a plurality of spatially-separated reaction zones including a first reaction zone and a second reaction zone, each of the reaction zones communicating with a gas source, each of the reaction zones comprising an axis perpendicular to an opening in each of the reaction zones, each opening configured to accept a substrate surface. The apparatuses further comprise a substrate support platform configured to move a plurality of substrates among the reaction zones during deposition and a control system configured to control movement of the substrate support platform and to pulse a first reaction gas into the first reaction zone and to pulse a second reaction gas into the second reaction zone during deposition, with at most one reaction gas pulsed in each reaction zone.

In yet another embodiment of the invention, multi-wafer atomic layer deposition (ALD) apparatuses are provided. The apparatuses comprise a plurality of walls defining at least a first reaction space and a second reaction space, the first reaction space and second reaction space separated by at least one separating wall, wherein the at least one separating wall comprises a gas flow passage communicating with a source of purge gas. The apparatuses further comprise a platform configured to support at least two substrates, the platform configured to move substrates vertically and laterally between the first reaction space and the second reaction space.

All of these embodiments are intended to be within the scope of the invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

The invention will be better understood from the Detailed Description of the Preferred Embodiments and from the appended drawings, which are meant to illustrate and not to limit the invention, and wherein:

FIGS. 1A and 1B are graphical illustrations of space separation and time separation pulsing methods, respectively, in accordance with prior art atomic layer deposition (ALD) methods;

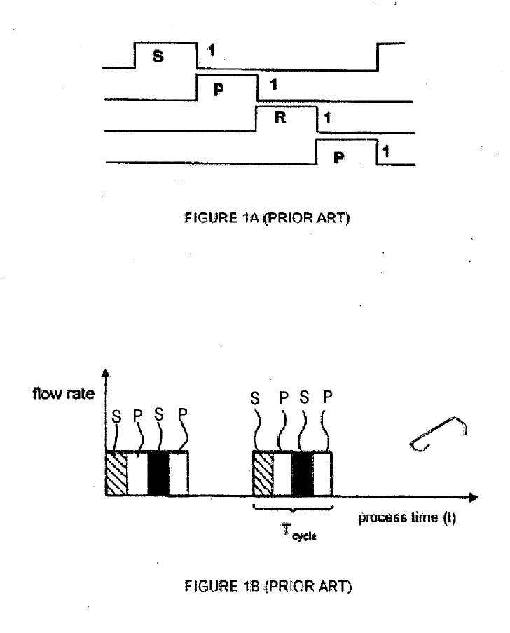

FIG. 2 is a schematic perspective view of a multi-wafer ALD apparatus, in accordance with a preferred embodiment of the invention;

FIG. 3 is a schematic, top-plan view of the multi-wafer ALD apparatus of FIG. 2, in accordance with a preferred embodiment of the invention;

FIGS. 4A and 4B are schematic, sequential illustrations of gas flow and wafer movement, relative to two reaction spaces of an ALD apparatus, in accordance with a preferred embodiment of the invention;

FIGS. 5A-5F are schematic, top-plan views of multi-wafer ALD apparatuses, in accordance with a preferred embodiment of the invention;

FIG. 6 is a schematic perspective cross-section of the multi-wafer ALD apparatus of FIGS. 4A and 4B, in accordance with a preferred embodiment of the invention;

FIGS. 7A-7C are schematic, sequential illustrations of wafer processing steps, in accordance with a preferred embodiment of the invention;

FIGS. 8A-8F are schematic, sequential illustrations of gas flow and wafer movement relative to one reaction space, in accordance with a preferred embodiment of the invention; and

FIGS. 9A and 9B are graphical illustrations of a space and time co-divided pulsing method from the perspective of reaction spaces and a wafer passing therethrough, respectively, in accordance with a preferred embodiment of the invention.

### DETAILED DESCRIPTION OF THE PREFERRED EMBODIMENTS

The inventors have observed several problems associated with prior art multi-wafer ALD systems. For example, in systems employing the space separation method, variation of pulsing times (variable pulsing frequency) between reaction spaces is not possible. As another example, in systems employing the space separation method, moving parts supporting wafers are also contacted with reactant gases. Film deposition occurs on the wafer supporting moving parts as well as wafer surfaces, leading to problems associated with particle generation. This is particularly problematic in systems configured for in situ (or direct) plasma generation using an RF electrode placed in the reaction space, in which metallic film deposition on reactor walls may lead to electrical shorting between the walls of the reactor and the RF electrode. This may significantly impede, even prevent, plasma generation.

Preferred embodiments of the present invention resolve the problems and shortcomings associated with prior art systems and methods. As an example, particle generation using apparatuses and methods of preferred embodiments is significantly reduced, if not eliminated. As another example, the space and time co-divided pulsing methods of preferred embodiments (described below) enable flexibility in pulsing frequency, which is advantageous for environments in which rapid or frequent changes in ALD recipes may be desired, such as research and development or small volume production. Advantageously, changes to pulse sequences can be made without hardware adjustment. Reaction spaces of preferred apparatus may be used in either ALD or CVD modes of operation.

Definitions

In context of the present invention, an “ALD process” or “ALD type process” generally refers to a process for producing films or thin films over a substrate in which a thin film is formed in a molecular monolayer-by-monolayer due to self-saturating chemical reactions. The general principles of ALD are disclosed, e.g., in U.S. Pat. Nos. 4,058,430 and 5,711,811, the disclosures of which are incorporated herein by reference. In an ALD process, gaseous reactants, i.e., precursors or source materials, alternately and sequentially contact a substrate to provide a surface reaction. Consequently, only up to one monolayer (i.e., an atomic layer or a molecular layer) of material is deposited at a time during each pulsing cycle. Typically, large reactant molecules (including ligands that aid self-termination of adsorption reactions) prevent full access to all reaction sites, causing steric hindrance and limiting deposition rates to less than one full molecular monolayer per cycle. Gas phase reactions between precursors and any undesired reactions of by-products are inhibited because precursor pulses are separated from each other. In a typical ALD reactor, the substrate remains in a single reaction chamber which is alternately pulsed with at least two reactants separated in time, and the reaction chamber is purged with an inactive gas (e.g., nitrogen, argon, or hydrogen) and/or evacuated using, e.g., a pumping system between precursor pulses to remove surplus gaseous reactants and reaction by-products from the chamber. Thus, the concentration profiles of the reactants in the reaction space with respect to time are not overlapping.

A “CVD process” or “CVD type process” designates a process in which deposition is carried out by bringing a substrate in contact with vapor phase source materials or compounds, whereby the source materials react with one another. In a CVD process, the source materials needed for the thin film growth are present in the reaction space at the same time during at least part of the deposition time. Thus, the concentration profiles of the source materials in the reaction space with respect to time are overlapping.

Another process somewhere between above mentioned “ALD process” and typical “CVD process”, sometimes called “digital CVD” or “pulsed CVD,” in which the supply of vapor phase source materials is modulated. In a pulsed CVD process, some amount of gas phase reaction (overlap in supply of the reactants) and/or more than a monolayer deposition per cycle is allowed in order to achieve higher deposition rates. Complete overlap of two or more reactants in all pulses can be considered a pulsed form of CVD, whereas partial overlap can be considered a modified version of ALD with some CVD-like reaction.

“Reaction space” is used to designate a reactor, a reaction chamber (“chamber”), a reaction zone, a reaction environment, or an arbitrarily defined volume in which conditions can be adjusted to effect desired reactions. Typically, the reaction space includes surfaces subject to all reaction gas pulses from which gases or particles can flow to the substrate (by entrained flow or diffusion) during normal operation.

“Substrate” can include any workpiece on which deposition is desired. Semiconductor wafers, for example, are often employed for integrated circuit (“IC”) fabrication. Typical substrates include, without limitation, silicon wafers, silica or quartz and glass plates used for flat panel displays. “Substrate” is meant to encompass bare substrates as well as partially fabricated substrates with layers and patterns formed thereon, including one or more layers formed in prior ALD cycles.

“Purge gas” can include any non-reactive gas or vapor. Purge gas may include, without limitation, an inert or inactive gas, such argon (Ar), helium (He), or nitrogen (N₂). Hydrogen (H₂) gas or oxygen (O₂) gas also may be used as purge gas if it does not involve gas phase reaction, i.e., under conditions in which they are non-reactive, for example, at a low temperatures without plasma activation. In some cases, purge gas may include “carrier gas,” which is used to direct a reactant into a reaction space. Additionally, different purge gases may be used in different parts of the apparatus. For example, one reaction space may be purged with Ar while another reaction space may be purged with N₂. Additionally, a reaction space may use more than one purge gas. For example, Ar may be used to purge a reactant gas and N₂ may be used as purge gas while moving wafers.

Vertical, horizontal, lateral, up, down, upper and lower are meant to represent relative directions of motion, not absolute orientations with respect to Earth.

Multi-Wafer ALD Apparatus

A space and time co-divided multi-substrate ALD apparatus, also referred to herein as a “semi-batch deposition apparatus”, of a preferred embodiment of the invention comprises a plurality of spatially-separated (or non-overlapping) reaction spaces, with each reaction space configured to accept a gas or a plurality of gases for processing a plurality of wafers. The gases may have the same composition or different compositions. In preferred ALD configurations, each reaction space is subjected to purge gas and only one reaction gas (or gas mixture) exclusively and the reaction spaces of apparatuses of preferred embodiments are substantially isolated from one another. As such, each reaction space can provide a different chemical environment with respect to another reaction space. Since each reaction space sees only one reactant, no film is deposited on stationary parts defining the reaction spaces, and thus problems associated with particle generation and contamination are significantly reduced, if not eliminated.

In preferred embodiments, the multi-wafer ALD apparatus is configured to perform vapor processing by pulsing a first reactant gas into a first reaction space for a first period of time and performing a reactant removal step thereafter. Reactant removal includes, without limitation, purging and/or pumping the first reaction space. Preferably, the reaction spaces are purged between reactant pulses. The multi-wafer ALD apparatus is configured to subsequently move the wafer vertically and laterally with respect to the first reaction space to a second, different reaction space and perform wafer processing in the second reaction space by pulsing a second reactant gas (or vapor) into the second reaction space for a second period of time. Preferably, lateral movement comprises rotating a substrate support platform. In some embodiments, the substrate support platform is a substrate susceptor configured for absorbing externally generated energy, such as inductive or radiant energy. In other embodiments, the substrate support platform is a heated chuck configured for internal (e.g., resistive) heating.

Reference will now be made to the figures, wherein like numerals refer to like parts throughout. It would be appreciated that the figures are not necessarily drawn to scale.

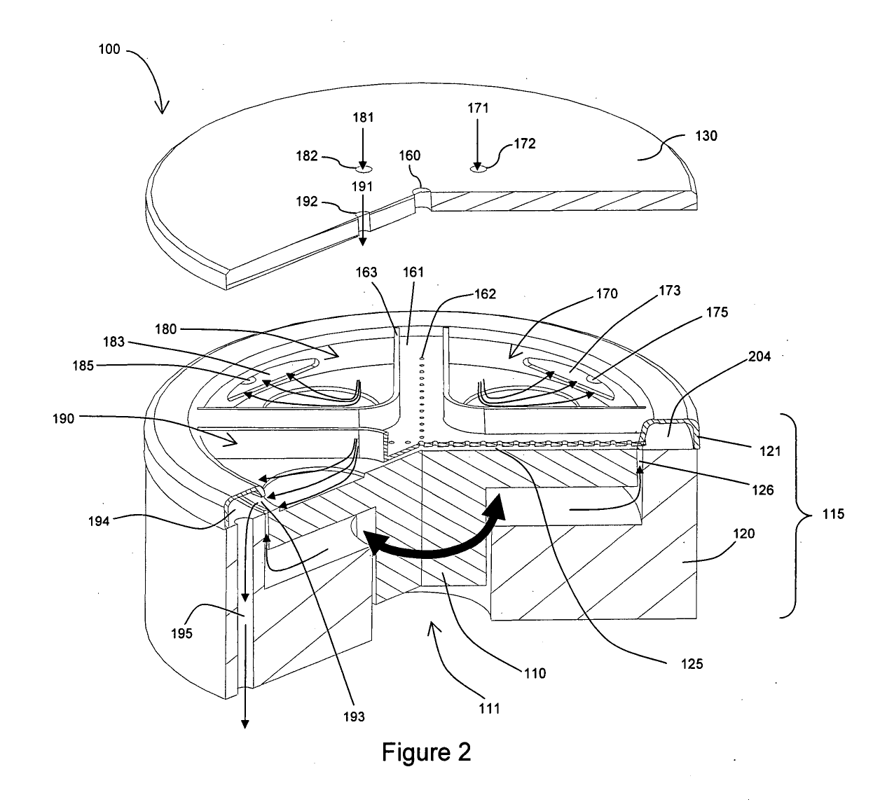

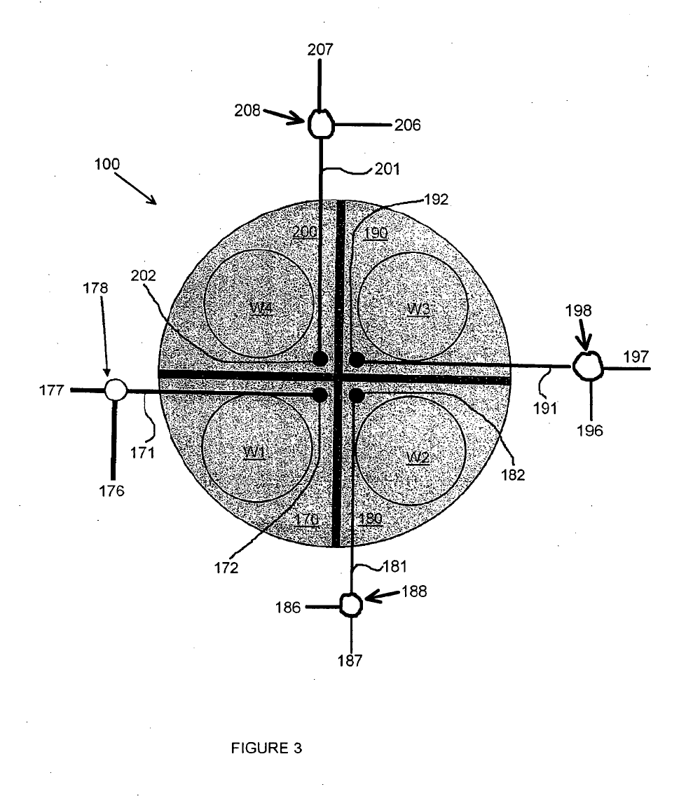

A multi-wafer ALD apparatus 100 according a preferred embodiment of the invention is shown in FIGS. 2 and 3. It will be understood that the apparatus 100 is part of a larger system or reactor, including loading subsystems (e.g., loading platform(s), load back chamber(s), robotics), gas distribution systems and control systems (e.g., memory, processor(s), user interface, etc.) programmed to conduct the sequences taught herein. A schematic top-plan view of the multi-wafer ALD apparatus of FIG. 2 is shown in FIG. 3. As noted above, orientations should be considered relative to other parts of the apparatus 100, rather than relative to Earth.

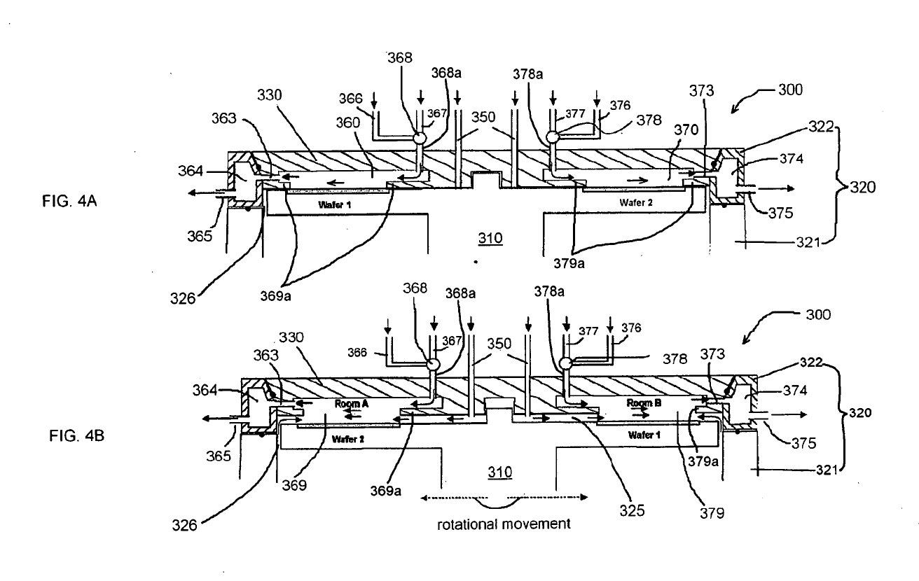

The multi-wafer ALD apparatus 100 (“the apparatus”) of the illustrated embodiment comprises a bottom portion 115 and a top portion (or cover) 130. The bottom portion 115 further comprises a lower section 120 and an upper section 121. The apparatus 100 of the illustrated embodiment comprises four reaction spaces 170, 180, 190, and 200, with each reaction space (or reaction zone) having a bottom opening (see below). A substrate support platform 110 is configured to transfer substrates or wafers W1-W4 among the reaction spaces. In the illustrated embodiment, the reaction spaces 170, 180, 190, and 200 are separated by a purged wall defined by vertical risers 163, the purged wall having internal spaces or channels 161 configured to accept purge gas from opening 160 in the cover 130 and direct purge gas to an area (or space) 125 below the reaction spaces through openings 162. The area 125 is disposed between the substrate support platform 110 and the cover 130/upper body 121. Each of the reaction spaces 170, 180, 190, and 200 is defined by a plurality of walls, the plurality of walls including the cover 130, the vertical risers 163, a substrate (that is in place) and the substrate support platform 110 at a lower portion of each of the reaction spaces. In other embodiments, as will be discussed below in the context of FIGS. 4, 6 and 8, the lower portion of each of the reaction spaces may be defined by a horizontal wall with an opening configured to accept a substrate surface. In the illustrated embodiment, reaction space 170 is adjacent to reaction space 180, reaction space 180 is adjacent to reaction space 190, reaction space 190 is adjacent to reaction space 200, and reaction space 200 is adjacent to reaction space 170. The cover 130 is configured to seal the top opening of each of the reaction spaces 170, 180, 190, and 200, in addition to the opening atop space 161. Each reaction space is configured to accept a gas through inlet openings (or pores) 172, 182, 192, and 202 in the cover 130 (see FIG. 3), and expel the gas through outlet (or exit) openings 173, 183, and 193 at the sides of each of each the reaction spaces and vertical exit passages 175, 185, and 195. Note that FIG. 2 shows the outlet openings and vertical exit passages for only three of the four reaction spaces. A reaction space may be equipped with a gas dispersing means (not shown) to disperse gas coming from inlet opening 172, 182, 192, or 202 over substrates, which may be a showerhead, a trumpet, or any other shape known to those of skill in the art.

With continued reference to FIG. 2, the bottom portion 115 of the apparatus 100 includes a lower body 120 and an upper body 121. The upper body 121 is configured to accept the cover 130. The cover rests upon the vertical risers 163.

With reference to FIG. 2 (showing 3 of the 4 reaction spaces), gas may exit the reaction spaces 170, 180, 190 through gas exit openings (or slits) 173, 183, 193 at the sides of the reaction spaces. Gas is subsequently directed to one or more passages disposed in the upper section 121, and thereafter to exit passages 175, 185, 195 disposed in the lower section 120. The exit passages out of the reaction spaces are preferably separated from each other. As a consequence, gas-phase mixing of reactants, which can generate particles, is either avoided completely or occurs sufficiently downstream away from the reaction spaces that contamination of the reaction spaces does not occur. Each passage may be in fluid communication with a dedicated pumping system. In cases where a shared pumping system is used to reduce costs, the passages should be joined sufficiently downstream away from each of the reaction spaces in order to prevent particles from entering the reaction spaces. Arrows indicate directions of general gas flow in the apparatus.

Wafers W1-W4 have top surfaces that are at least partially exposed to the reaction spaces 170, 180, 190, and 200. With reference to FIG. 3, the top surface of W1 is exposed to reaction space 170, the top surface of W2 is exposed to reaction space 180, the top surface of W3 is exposed to reaction space 190 and the top surface of W4 is exposed to reaction space 200. In some embodiments, the substrate support platform 110 may seal, or effectively seal the opening of a reaction space by close proximity with the walls defining the reaction spaces. In cases where a reaction space is not truly sealed (i.e., a gap exists between the upper section 121 and the substrate support platform 110), purge gas preferably flows under the channel 161 (FIG. 2) to the space 125 to isolate the reaction spaces.

In the illustrated embodiment, the substrate support platform 110 comprises a rotatable shaft configured to rotate in the direction of the arrow. The substrate support platform 110 may rotate in a continuous or step-wise fashion. In some embodiments, the substrate support platform 110 rotates via back-and-forth rotational motion. The space disposed between the substrate support platform 110 and the lower body 120, is purged with a purge gas in order to prevent reactants from entering into the space and meeting each other to generate particles. Continuous purge gas flow upward to reaction spaces is maintained through a gap 126 between the lower body 120 and the substrate support platform 110. Purge gas is exhausted through outlet openings 173, 183, and 193.

As will be appreciated from the description of FIGS. 4, 6 and 8 below, in some embodiments the substrate support platform is configured to move (or translate) vertically with respect to the reaction spaces. This vertical motion moves wafers away from the reaction spaces, revealing openings at horizontal lower portions of each of the reaction spaces.

With reference to FIG. 3, vapor is directed into reaction spaces 170, 180, 190, and 200 using gas lines 171, 181, 191, and 201, respectively. Each of the gas lines 171, 181, 191, and 201 may be a cylindrical tube or, generally, any structure configured to convey gas. As an example, the gas line may be stainless steel gas tubes. Gas lines 171, 181, 191, and 201 are configured to accept gas (or vapor) from reactant lines 176, 186, 196, and 206 and purge gas lines 177, 187, 197, and 207. Thus, each reaction space communicates with a purge gas source and only one reactant source. Some reaction spaces may be used only for purging. Such reaction spaces may be configured with purge gas lines only, omitting reactant lines. In the illustrated embodiment, reactant lines 176, 186, 196 and 206 meet purge gas lines 177, 187, 197 and 207 at intersection points. In some embodiments, the intersection points are switches 178, 188, 198, and 208 that dictate which of the reactant or purge gas lines is permitted to communicate with the gas lines 171, 181, 191, and 201. The switches 178, 188, 198, and 208 may be controlled by a computer system (not shown) configured to control wafer processing. The inner surfaces of each of the gas lines 171, 181, 191, and 201 is preferably non-reactive with the reactant with which it communicates.

The gas lines will now be described in the context of reaction space 170. It would be appreciated that the gas lines associated with the other reaction spaces (reaction spaces 180, 190 and 200) can function in a similar manner.

In one embodiment, intersection point 178 is a gas switch or a three-way valve configured to select which of the gases from the lines 176 or 177 is permitted to enter the gas line 171. For example, with the switch 178 in a “reactant feed” configuration, the reactant gas (which may include an inactive carrier gas) from line 176 will be allowed to enter line 171 and subsequently reaction space 170. With the switch 178 in the reactant feed configuration, gas from the purge line 177 will not enter line 171. With the switch in a “purge gas” configuration, purge gas from line 177 will be allowed to enter line 171 and subsequently reaction space 170. With the switch in the purge gas configuration, gas from the reactant line 176 will not enter line 171. As an alternative, the switch 178 may include a configuration which permits mixing of the gases from lines 176 and 177. If reactant line 176 includes a vapor reactant and purge gas line 177 includes a carrier gas, this configuration may permit mixing of the vapor reactant with the carrier gas, e.g., to control the partial pressure of reactant gas directed to reaction space 170, or inert carrier gas could be mixed with reactant upstream of the switch 178. In one arrangement, purge gas can flow continually while reactant gas is pulsed.

Another preferred embodiment of the invention is shown in FIGS. 4A and 4B. With reference to FIG. 4A, the multi-wafer ALD apparatus 300 comprises a bottom portion 320 and a cover 330. The bottom portion 320 includes a lower section 321 and an upper section 322. The multi-wafer ALD apparatus of the illustrated embodiment includes a plurality of reaction spaces 360 and 370, reactant gas inlet passages 366 and 376, purge gas (or carrier gas) inlet passages 367 and 377, gas outlet passages 363 and 373 and a rotating substrate support platform 310. The reaction spaces 360 and 370 comprise openings 369 and 379, respectively, which are defined by horizontal lower portions 369a and 379a of the reaction spaces. The reaction spaces 360 and 370 are partially defined by the walls of the cover 330, including the horizontal lower portions 369a and 379a, vertical walls next to the horizontal lower portions 369a and 379a, and horizontal walls disposed generally above the reaction spaces 360 and 370, and openings 369 and 379. The rotating substrate support platform 310 supports a plurality of wafers (“Wafer 1” and “Wafer 2”). The gas outlet passage 363 and 373 directs gas into exhaust passages 364 and 374, and subsequently into outlet passages 365 and 375, which are separated from each other. Gas inlet passages 366 and 367 meet at intersection point 368, and gas inlet passages 376 and 377 meet at intersection point 378. Gas is directed into reaction spaces 360 and 370 through passages 368a and 378a, respectively. In some embodiments, the intersection points 368 and 378 are gas switches configured to permit either purge gas or the reactant gas into each of the reaction spaces 360 and 370. In other embodiments, the intersection points 368 and 378 are gas switches configured to permit a degree of mixing between vapor in the reactant gas inlet passages 366 and 376 and gas in the purge gas inlet passages 367 and 377. In yet other embodiments, the intersection points 368 and 378 are gas switches configured to permit pulsing of the reactant gas from gas inlet passages 366 and 376 while permitting continuous flow from the purge gas inlet passages 367 and 377. The reaction spaces 360 and 370 are configured to receive a first reactant gas and a second reactant gas, respectively. Additionally, each of the reaction spaces 360 and 370 is configured for purging with an inert gas or carrier gas (e.g., Ar, He, N₂, H₂, a mixture of these gases). The cover 330 includes passages 350 configured to direct purge gas through an area 325 between the reaction spaces and the substrate support platform during wafer movement.

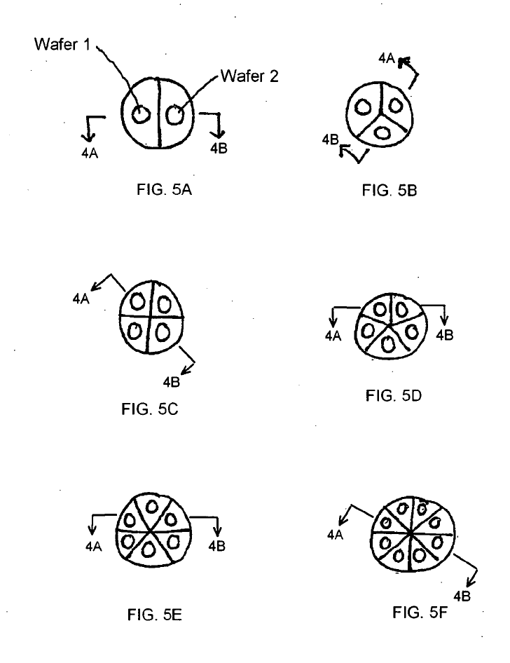

While FIGS. 4A and 4B show only two reaction spaces, it will be appreciated that any number of reaction spaces can be used. For example, the multi-wafer ALD apparatus 300 may include two, three, four, five, or ten reaction spaces. To illustrate this point, FIGS. 5A-5F are schematic, top-plan views of various embodiments of the multi-wafer ALD apparatus of FIGS. 4A and 4B. FIG. 5A-5F are two, three, four, five, six and eight reaction space embodiments, respectively, of the multi-wafer ALD apparatus of FIGS. 4A and 4B, with lines 4A-4B indicating the cross-sections that may be selected to coincide with FIGS. 4A and 4B. It will be understood that not all of these embodiments are compatible with both wafer positions of FIGS. 4A and 4B, but that in all of these arrangements each of any given two wafers can pass through both of any given two reaction spaces.

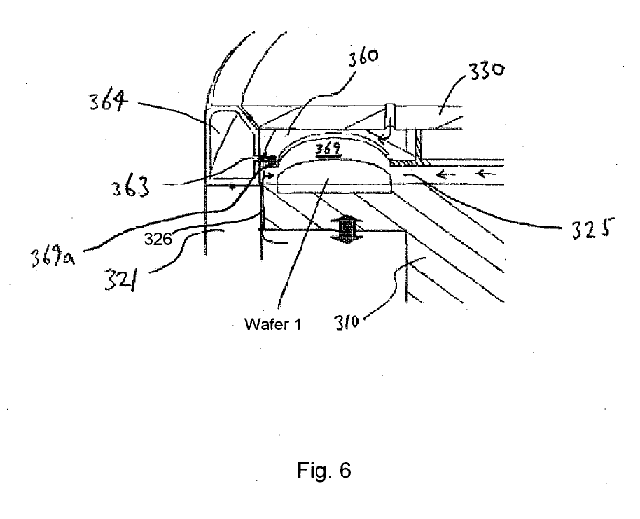

With reference to FIG. 6, in a schematic perspective view of the multi-wafer ALD apparatus of FIGS. 4A and 4B, vertical movement of the substrate support platform 310 reveals an opening 369 in reaction space 360 and openings (not shown) in the other reaction spaces. In the illustrated embodiment, the opening 369 is disposed within the horizontal lower portion 369a of the reaction space 360. Similarly, openings of reaction space 370 and other reaction spaces are disposed within corresponding horizontal lower portions. The opening 369 of reaction space 360 is configured to accept a wafer (Wafer 1, as illustrated). In some embodiments, the opening 369 is configured to accept the entire wafer including portions of the substrate support platform in proximity to the wafer. Preferably, the amount of surface of the substrate support platform 310 exposed to reaction gases in the reaction space 360 is minimized. Preferably, the opening is sealable, more preferably hermetically sealable. In other embodiments, the substrate support platform is configured to place Wafer 1 is proximity to the opening such that a gap is formed between the top surface of Wafer 1 and the horizontal lower portion of reaction space.

With continued reference to FIG. 6, in some embodiments, contact between the substrate support platform 310 (or the top edge of the surface of Wafer 1) and the horizontal lower portion 369a seals the opening 369 such that gas (reactant and/or purge gas) flow from the opening 369 to the common transport area below the reaction space 360, and vice versa, is prohibited or minimized. Vertical movement of the substrate support platform 310 breaks the seal, thereby revealing the opening 369.

The substrate support platforms of preferred embodiments (110 and 310 of FIGS. 2 and 4A) may include gas flow passages for preventing “backside deposition” and “autodoping.” Backside deposition involves flow of reactant gases through a gap region between a wafer (or substrate) and substrate support platform, followed by deposition of material on the backside of a wafer. Autodoping is the tendency of dopant atoms to diffuse downward through the wafer, emerge from the substrate backside, and then travel between the substrate and the substrate support platform up around the substrate edge to redeposit onto the substrate front side, typically near the substrate edge. These redeposited dopant atoms can adversely affect the performance of the integrated circuits, particularly semiconductor dies from near the substrate edge. Autodoping tends to be more prevalent and problematic for higher-doped substrates. Backside deposition and autodoping may lead to problems with particle contamination and, ultimately, poor device performance. However, the substrate support platforms may include gas flow passages (not shown) in fluid communication with the undersides (or backsides) of wafers, which would reduce (if not eliminate) backside deposition and autodoping during wafer processing. Examples of single wafer substrate support platforms configured for preventing backside deposition and autodoping are found in U.S. Patent Publication No. 2005/0193952 and U.S. Pat. No. 6,113,702, the disclosures of which are incorporated herein by reference. The teaching of these systems may be incorporated in some of the embodiments of the invention.

It would be appreciated that several alternatives and modifications of the apparatus 100 are possible without departing from the scope of the invention. As an example, while four reaction spaces 170, 180, 190, and 200 are shown in FIGS. 2 and 3 and two reaction spaces 360 and 370 are shown in FIGS. 4A and 4B, the apparatuses 100 and 300 may include any number of reaction spaces, depending upon the desired number of reaction spaces, coordinated with the desired sequence of exposure, the number of reactants and/or purge gases used. As an example, if a wafer is to be introduced to two different reactants, the apparatuses 100 and 300 may include 2, 4, 6, 8, or 10 reaction spaces. As another example, if a wafer is to be introduced to three different reactants (e.g., WF₆, NH₃, and B(C₂H₅)₃ for ALD of WNₓC_{y} via a “three-step” deposition process), the apparatuses 100 and 300 may include 3, 6, or 9 reaction spaces. Additionally, the substrate support platform 110 may be configured to support any number of wafers, preferably less than or equal to the number of reaction spaces. As an example, the substrate support platform 110 may be configured to support between 2 and 10 wafers, underlying a corresponding number of reaction spaces. The skilled artisan will understand that the number of reaction spaces need not directly relate to the number of reactant gases used. For example, an apparatus configured to pulse two different reactants can have three reaction spaces, where one of the reaction spaces may be configured to flow only a purge gas. Similarly, dedicated purging chambers can be provided in any of the arrangements having more spaces than number of ALD reactants. Furthermore, at least one reaction zone or space is provided for each ALD reactant. As another example, although the illustrated reaction spaces of FIGS. 2 and 3 are rotationally disposed in relation to one another, they need not be. For example, the reaction spaces may be disposed linearly with respect to one another. In such a case, the substrate support platform may be configured to move the wafers from one reaction space to the next laterally in a “conveyer belt” fashion. As still another example, while each reaction space is associated with one reactant gas line any number of gas lines (and openings into the reaction spaces) can be used. Each gas line can have a predetermined number of purge gas lines, reactant gas lines and intersection points. As still another example, at least one of the reaction spaces may be configured for plasma generation. In such a case, the at least one reaction space may include an in situ (or direct) plasma generator, such as the capacitively-coupled RF electrode within the reaction space disclosed in U.S. Pat. No. 6,539,891, the entire disclosure of which is incorporated herein by reference. The RF electrode may be in a form of a showerhead. As another example, one or more of the reaction spaces may be configured to receive excited species (e.g., ions and radicals) from a remote plasma (or radical) generator. As another example, any configuration of purge and/or exhaust paths may be used.

Operation of the Multi-Wafer ALD Apparatus

Wafer processing according to preferred embodiments may be accomplished, without limitation, by step-wise rotation of the substrate support platform, which may include “rotate-back” (or “back-and-forth”) motion. The substrate support platform moves wafers sequentially through different reaction zones. An ALD cycle is completed when a wafer is passed through the total number of different reaction zones, which may require a whole or a partial rotation of the substrate support platform. In one embodiment, continuous rotation (e.g., clockwise) will return the wafer back to the first reaction space. In another embodiment, rotation is reversed after completing one circuit of the desired number of reaction spaces, e.g., reversing from clockwise to counter-clockwise rotation, either directly back to the first reaction space or by again employing the intervening spaces in reverse order.

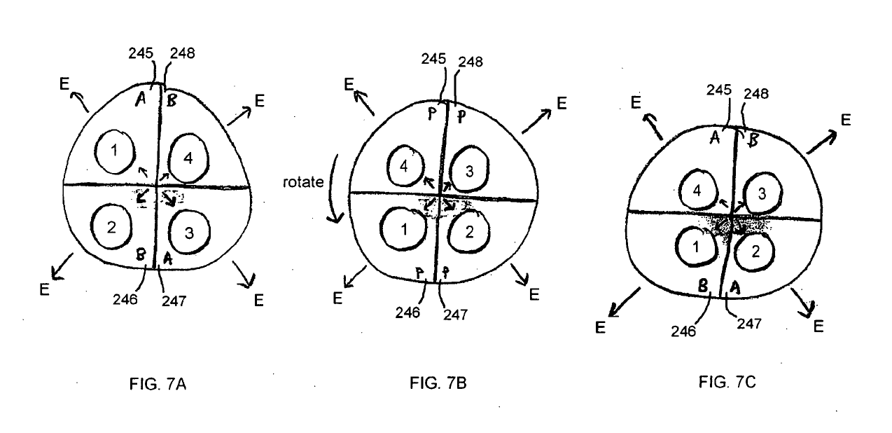

With reference to FIGS. 7A-7C, in a preferred embodiment of the invention, a multi-wafer ALD apparatus, such as that provided by FIGS. 2 and 3, is used to process a plurality of wafers. As shown in FIG. 7A, with a first wafer (“1”) exposed to a first reaction space 245, a second wafer (“2”) exposed to a second reaction space 246, a third wafer (“3”) exposed to a third reaction space 247 and a fourth wafer (“4”) exposed to a fourth reaction space 248, a first reactant (“A”) is pulsed into the first and third reaction spaces 245 and 247 for a first time period, and a second reactant (“B”) is pulsed into the second and fourth reaction spaces 246 and 248 for a second time period. The first time period may be equivalent to the second time period. Advantageously, however, the methods described herein afford the flexibility to employ different reactant pulse times for different reactants (in different reaction spaces), despite the fact that the rotary platform ensures the same residence times for each wafer in the various reaction spaces at the same time. Thus, alternating reactant and purge gases in each chamber enable narrowing the pulse duration relative to wafer residence time for greater ALD recipe flexibility. During pulsing, the first and second reactants A and B (in addition to any reaction by-products) are exhausted (“E”) from the reaction spaces 245-248. The exhaust passages, which are configured to direct excess reactants and reaction by-products out of the reaction spaces 245-248, are separated from each other as described above. The first and second reactants A and B preferably react with the surfaces of the first and second wafers, respectively, to deposit a monolayer of material on the surfaces. In the illustrated four reaction space embodiment, reactants A and B are also exposed to the third and fourth wafers, respectively. Alternatively, the first and second reactants A and B may chemically modify existing films on the surfaces. In some embodiments, the first and/or second reactants may include plasma-excited species of a vapor phase species, such as, e.g., hydrogen (H₂).

After each of the first and second time periods, the first and second reactants A and B (and any reaction by-products) are removed from the first and second reaction spaces preferably with the aid of a purge gas (“P”) and/or vacuum generated by a pumping system. In some embodiments, there is a time lag between the time in which pulsing is terminated and the time in which purging is initiated. In other embodiments, there is no time lag, i.e., purging is initiated immediately after pulsing is terminated. Preferably, the first, second, third and fourth wafers spend the same amount of time in each of the reaction spaces 245-248 (i.e., the wafers have equivalent residence times in each of the reaction spaces). At least one of, and preferably both of the first and second time periods are shorter than the residence time.

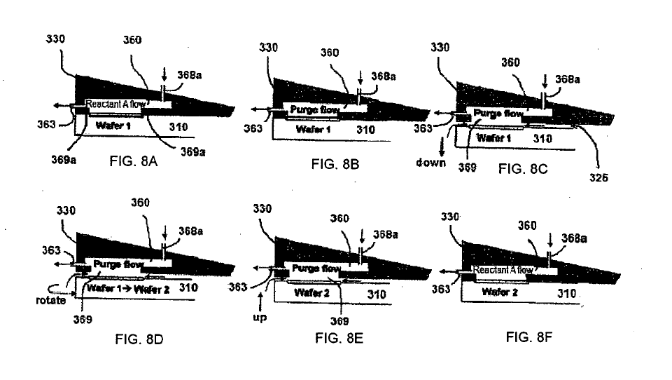

Next, as shown in FIG. 7B, the first wafer is laterally moved to an area below the second reaction space 246, the second wafer is laterally moved to an area below the third reaction space 247, the third wafer is laterally moved to an area below the fourth reaction space 248 and the fourth wafer is laterally moved to an area below the first reaction space 245. The lateral movement may be coupled with vertical movement, which is explained below with reference to FIGS. 4A, 4B and 8A-8F. The reaction spaces 245-248 are preferably purged and/or pumped during movement. In the illustrated embodiment, the second reaction space 246 is rotationally adjacent to the first and third reaction spaces 245 and 247, and the fourth reaction space 248 is rotationally adjacent to the first and third reaction spaces 245 and 247. Lateral movement is preferably accomplished by rotational movement of a substrate support platform configured to support the first and second wafers.

Next, as shown in FIG. 7C, with the top surface of the first wafer exposed to the second reaction space 246, the top surface of the second wafer exposed to the third reaction space 247, the top surface of the third wafer exposed to the fourth reaction space 248 and the top surface of the fourth wafer exposed to the first reaction space 245, the second reactant B is pulsed into the second and fourth reaction spaces 246 and 248 for the second time period and the first reactant is pulsed into the first and third reaction spaces 245 and 247 for the first time period. The first and second reactants may A and B react with the top surfaces of the first, second, third and fourth wafers to alter the material on the surfaces, which may include depositing a film of material on the surfaces or chemically modifying (e.g., reducing, nitriding, carburizing, or oxidizing) existing films.

After each of the first and second time periods, the first and second reactants (and any reaction by-products) are removed from the first, second, third and fourth reaction spaces 245-248 with the aid of a purge gas and/or vacuum generated by a pumping system.

Next, each wafer is moved laterally to an area below an adjacent reaction space. The reaction spaces 245-248 are preferably purged and/or pumped during the movement. The first wafer may be laterally moved to an area below the third reaction space 247, the second wafer may be laterally moved to an area below the fourth reaction space 248, the third wafer may be laterally moved to an area below the first reaction space 245, and the fourth wafer may be laterally moved to an area below the second reaction space 246. Subsequent to the lateral motion, the top surface of the first wafer is exposed to the third reaction space 247, the top surface of the second wafer exposed to the fourth reaction space 248, the top surface of the third wafer exposed to the first reaction space 245 and the top surface of the fourth wafer exposed to the second reaction space 246. Next, the first and third wafers are exposed to (or contacted with) the first reactant A and the second and fourth wafers are exposed to the second reactant B. Alternatively, in a rotate-back motion, the first, second, third and fourth wafers may be laterally moved to areas below the first, second, third and fourth reaction spaces 245-248, respectively. With the wafers exposed to the respective reaction spaces, the first and third wafers may be exposed to the first reactant A and the second and fourth wafers may be exposed to the second reactant B. Such rotate-back motion may advantageously facilitate gas and/or electrical connections without expensive universal joints required for continuous rotation. In either case, the wafers may be rotated among the reaction spaces to continue processing. Processing may continue until films of predetermined thicknesses are formed over the wafers. In some embodiments, the abovementioned processing steps are repeated at least ten times.

The illustrated embodiment may be suited for a “two-step” deposition process, in which a wafer is sequentially and alternately exposed to two reactant gases. In this embodiment, an ALD cycle is complete with a half rotation of the substrate support platform through two steps, with a quarter of a complete rotation per step. While in the illustrated embodiment reactant A is pulsed into the first and third reaction spaces 245 and 247 and reactant B is pulsed into the second and fourth reaction spaces 246 and 248, in some cases each reaction space may be exposed to a different reactant. This may be suitable for a “four-step” deposition process in which a wafer is sequentially introduced to four reactants. In cases where a “three-step” deposition process is desired, one of the four reaction spaces may be configured to pulse a purge gas only (i.e., a wafer exposed to that reaction space is not contacted with a reactant gas during the residence time), and the remaining three reaction spaces are each pulsed with a different reactant. As an alternative, only two of the reaction spaces may be configured to receive reactants; the other two reaction spaces may be configured for purging, such that when a wafer is in those reaction spaces it is not contacted with a reactant gas. This configuration may facilitate purging of a “sticky” reactant or by-product because there is no need to completely purge the chamber wall (or plurality of chamber walls) defining the reaction space. The sticky reactant adhered on a wafer is removed in the reaction space dedicated to purging, while other wafers can use this time for reactant steps. In an embodiment where an apparatus comprises four reaction spaces, and a wafer is sequentially exposed to a first reactant, a first purge gas, a second reactant, and a second purge gas, an ALD cycle is complete with a full rotation of the substrate support platform through four steps of a quarter of a complete rotation per step. As another alternative, with the first and third reaction spaces 245 and 247 receiving the first reactant A and the second and fourth reaction spaces 246 and 248 receiving the second reactant B, the time the first reactant A is pulsed into the first reaction space 245 may differ from the time the first reactant A is pulsed into the third reaction space 247. Likewise, the time the second reactant B is pulsed into the second reaction space 246 may differ from the time the second reactant B is pulsed into the fourth reaction space 248. However, it should be understood that the residence time of each wafer in each reaction space is the same for any given cycle. Because purging is preferably initiated before lateral movement of the wafers, the pulsing times are preferably shorter than the residence time. As an example, if the first reactant A is pulsed into the first and third reaction spaces 245 and 247 for 0.5 and 1 seconds, respectively, and the wafer residence time in each reaction space is 1.5 seconds, after pulsing, the first reaction space 245 is purged for 1 seconds and the third reaction space 247 is purged for 0.5 second.

FIGS. 4A and 4B illustrate a sequence of processing steps in a preferred embodiment of the invention which includes vertical movement. With reference to FIG. 4A, lower portions of the cover 330 make contact with the rotating substrate support platform 310 to seal each of the reaction space openings 369 and 379. The lower portion may make contact with top edges of Wafer 1 and Wafer 2 to seal the openings. The seal is sufficient to prevent gases in the reaction spaces 360 and 370 (and other gases in other reaction spaces if the multi-wafer ALD apparatus includes more than two reaction spaces) from communicating with each other, and preferably to keep reactant gases only in the reaction spaces 360 and 370 and corresponding inlet and outlet passages. With the top surfaces of Wafer 1 and Wafer 2 exposed to reaction spaces 360 and 370, respectively, the first reactant gas is pulsed into reaction space 360 for a first period of time and the second reactant gas is pulsed into reaction space 370 for a second period of time. While typically overlapping, the first and second periods need not be identical. During pulsing, no area other than the reaction spaces is exposed to the first and second reactant gases. In some embodiments, during the pulses, the first and second reactant gases are permitted to continuously flow out of the reaction spaces 360 and 370 through outlet passages 363 and 373.

After the first period of time, the pulse of the first reactant gas is terminated. The first reactant gas is then removed from the reaction space 360 with, e.g., the aid of a purge gas. Initiation of purge gas flow may be simultaneous with termination of the flow of the first reactant gas. Purge gas is directed through gas inlet 367, and excess first reactant, reaction by-products and purge gas are permitted to exit the reaction space 360 through the outlet passage 363. Similarly, the pulse of the second reactant gas is terminated after the second period of time. The second reactant gas is then removed from the reaction space 370 with, e.g., the aid of a purge gas. Purge gas is directed through gas inlet 377 and permitted to exit the reaction space 370 through the outlet passage 373. Purging of the reaction spaces 360 and 370 after pulsing with the first and second reactant gases reduces (even eliminates) adsorption of the first and second reaction gases on parts of the substrate support platform 310 during vertical movement and rotation (see below) of the substrate support platform 310, in addition to reactive surfaces of Wafer 1 and Wafer 2.

As an alternative to purging with an inert gas, if the first reactant and/or second reactant gases are pulsed into reaction spaces 360 and 370 using a carrier gas (e.g., H₂), the first and/or second reactant gases may be removed by terminating the flow of the reactant gases and continuing to flow carrier gas (i.e., the carrier gas serves as the purge gas). In such a case, the carrier gas may be provided through a gas line associated with a reaction space (e.g., gas line 367 of reaction space 360) and the reactant gas may be provided through another gas line (e.g., gas line 366). In some cases, with inert gas valving, the flow of the purge gas may actually cause termination of the reactant gas, as disclosed in U.S. Pat. No. 6,783,590, the disclosure of which is incorporated by reference herein.

With reference to FIG. 4B, following exposure of Wafer 1 to the first reactant gas exposure of Wafer 2 to the second reactant gas, the substrate support platform 310 vertically moves Wafer 1 and Wafer 2 away from reaction spaces 360 and 370, respectively. After unsealing the openings 369 and 379, the substrate support platform 310 laterally moves or rotates Wafer 1 to an area below reaction space 370 while rotating Wafer 2 to an area below reaction space 360. During the movement of the substrate support platform 310, the reaction spaces 360 and 370 are continuously purged. Purge gas flows through passages 350 and an area 325 between the cover 330 and the substrate support platform 310 and also through a gap 326 between the substrate support platform 310 and the bottom portion of the apparatus 320, as shown by arrows. All purge gases flow into the reaction spaces and exit to outlet gas passages 363 and 373. After laterally moving the wafers, the substrate support platform 310 moves vertically upward to re-seal the openings 369 and 379. In the illustrated example, Wafers 1 and 2 have swapped positions.

With the top surfaces of Wafer 1 and Wafer 2 exposed to reaction spaces 370 and 360, respectively, the first reactant gas is pulsed into reaction space 360 for a first period of time and the second reactant gas is pulsed into reaction space 370 for a second period of time. Next the reaction spaces 360 and 370 are purged and the substrate support platform 310 shifts the positions of Wafer 1 and Wafer 2. These steps of pulsing reactants and shifting wafer positions are repeated until films of predetermined thicknesses are formed over the wafers.

While FIGS. 4A and 4B are illustrated as if upon rotation of the substrate support platform 310 Wafers 1 and 2 swap positions, it will be appreciated that other wafer-reaction space configurations are possible if the multi-wafer ALD apparatus 300 includes more than two reaction spaces. For example, a third wafer may appear in reaction space 360 when Wafer 1 moves to reaction space 370. As another example, a third wafer and a fourth wafer may appear in reaction spaces 360 and 370, respectively. Wafers 1 and/or 2 may also be rotated to intermediate reaction spaces.

An advantage of the embodiment illustrated in FIGS. 4A and 4B is that deposition is further limited only to reactive surfaces exposed to both of the reaction spaces 360 and 370. This is by virtue of the fact that in ALD deposition only takes place on reactive surfaces that are exposed to all of the reactants. In some embodiments, deposition only occurs on wafers when the openings of the reaction spaces are sealed by close proximity or contact between the lower portions of the reaction spaces and the edges of top surfaces of the wafers. In other embodiments, deposition occurs on the wafers and portions of the substrate support platform 310 exposed to the reaction spaces 360 and 370 when the openings of the reaction spaces are sealed by close proximity or contact between the lower portions of the reaction spaces 360 and 370 and portions of the substrate support platform 310 in proximity to the wafers. Little to no deposition on apparatus parts greatly reduces particle generation due to film flaking. Additionally, particle generation may be reduced (if not eliminated) if reactant gases in the exhaust passages downstream of the reaction spaces are separated from one another. The preferred embodiments can elongate operation time of the multi-wafer (or semi-batch) deposition apparatus between preventive maintenance operations.

While movement of the substrate support platform 310 away from the reaction spaces 360 and 370 was described as vertical followed by lateral (or rotational) motion, it will be appreciated that the substrate support platform 310 may alternatively be moved simultaneously vertically and laterally away from the reaction spaces, thereby descending diagonally from the reaction spaces. An initial vertical motion may aid in clearing any impediment (e.g., lower portions of the reaction spaces) to diagonal motion. Movement toward each of the reaction spaces can take place in a similar fashion, i.e., the substrate support platform 310 can move diagonally towards each of the reaction spaces 360 and 370.

FIGS. 8A to 8F illustrate a sequence of exemplary processing steps using a multi-wafer (or semi-batch) ALD apparatus of preferred embodiments illustrated in FIGS. 4A and 4B. For simplicity, the multi-wafer ALD apparatus of the illustrated embodiment shows one reaction space with only parts necessary for the explanation. However, it should be understood that the reaction space of the illustrated embodiment includes at least one other reaction space, which is not shown. For example, the multi-wafer ALD apparatus of the illustrated embodiment may include four reaction spaces.

With reference to FIGS. 8A-8F, the multi-wafer ALD apparatus of the illustrate embodiment comprises a cover 330 with a plurality of gas flow passages, a gas flow passage 368a for alternately pulsing purge and reactant gases into a reaction space 360, an exhaust passage 363 for directing gas out of the reaction space 360, and a substrate support platform 310 for supporting a plurality of wafers. The reaction space 360 comprises an opening 369, which may be sealed upon contact between the substrate support platform 310 (or a portion of the top surface of Wafer 1 as shown) and a horizontal lower potion 369a of an enclosure defining the reaction space 360.

With reference to FIG. 8A, with the top surface of a first wafer (“Wafer 1”) exposed to the reaction space 360, a first reactant (gas “A”) is pulsed into the reaction space 360 for a predetermined period of time. The first reactant A contacts the exposed top surface of Wafer 1. The predetermined period of time may be sufficient to saturate the exposed top surface of Wafer 1. For example, the first reactant A may serve to adsorb, largely intact, on the wafer, thereby forming a monolayer of material on the top surface of Wafer 1.

With reference to FIG. 8B, in a reactant removal step after the predetermined period of time, pulsing of gas A is terminated and excess gas A and any reaction by-products are removed from the reaction space 360 with the aid of a purge gas (as illustrated) and/or a vacuum generated by a pumping system. If gas A is pulsed into the reaction space 360 using a carrier gas (e.g., H₂), the removal step may include stopping the flow of gas A and continuing to flow the carrier gas. In this case, the carrier gas serves as the purge gas. In the illustrated sequence, purge flow replaces the reactant A flow prior to moving the substrate away from the reaction space 360.

Next, with reference to FIG. 8C, the substrate support platform 310 is moved vertically (in the direction of the down arrow) away from the reaction space 360. During vertical movement, the reaction space 360 and a space 325 below the reaction space 360 are preferably purged to prevent any excess reactants, reaction by-products and contaminants from escaping out of the reaction space 360 onto the substrate support platform 310. During purging of the space 325, purge gas may migrate around the sides of the substrate support platform 310 to exhaust passages (now shown), as described above in the context of FIG. 2. As the substrate support platform 310 moves vertically away from the reaction space 360, any seal formed between the substrate support platform 310 (or portions of the top surface of Wafer 1) and the horizontal lower portion 369a of the enclosure defining the reaction space 360 is broken, thereby revealing the opening 369. Purge gas flows into the reaction spaces through the opening 369 as well as through the passage 368a, and exits through the exhaust passage 363. Any reactant gas remaining in the reaction space 360 is purged from the reaction space through the exhaust passage 363 with purge gas flow. Vertical movement is terminated once the substrate support platform 310 has been moved a sufficient vertical distance away from the reaction space 360 to permit unimpeded lateral motion of the substrate support platform 310.

With reference to FIG. 8D, with Wafer 1 vertically moved below the reaction space 360, the substrate support platform 310 laterally moves Wafer 1 away from an area below the opening 369. In the illustrated embodiment, a second substrate (“Wafer 2”) is simultaneously moved below the opening 369. Wafer 1 may be moved below an opening of another reaction space (not shown) or transferred out of the multi-wafer ALD apparatus. Lateral movement in the illustrated embodiment is accomplished by rotation of the substrate support platform 310 about a central axis (not shown). Preferably during the lateral movement, the reaction space 360 and a space 325 below the reaction space 360 are purged to prevent any excess reactants, reaction by-products and contaminants from escaping out of the reaction space 360 onto the substrate support platform 310. Lateral movement (or rotation) is terminated once Wafer 2 is disposed below the opening 369.

Next, with reference to FIG. 8E, the substrate support platform 310 vertically moves Wafer 2 (in the direction of the up arrow) towards the reaction space 360. In the illustrated embodiment, vertical movement is terminated once the substrate support platform (or a portion of a top surface of Wafer 2) contacts the horizontal lower portion 369a of the enclosure defining the reaction space 360, thereby forming a seal between the substrate support platform (or the portion of the top surface of Wafer 2) and the horizontal lower portion 369a. In some embodiments, vertical motion is terminated when a gap of predetermined size (or distance) is formed between the substrate support platform 310 (or the portion of the top surface of Wafer 2) and the horizontal lower portion 369a of the enclosure. During vertical movement, the reaction space 360 and a space 325 below the reaction space 360 are preferably purged to prevent any excess reactants, reaction by-products and contaminants from escaping out of the reaction space 360 onto the substrate support platform 310.

With reference to FIG. 8F, with the top surface of Wafer 2 exposed to the reaction space 360, gas A is once again pulsed into the reaction space 360 for a predetermined period of time, which may be equivalent to the predetermined period of time used for processing Wafer 1. Gas A reacts with the top surface of Wafer 2 to, e.g., chemically modify an existing film or adsorb less than about one monolayer.

In the illustrated embodiments in which the reaction spaces are sealed in each step, the pressure of each of the reaction spaces is independently controllable during reactant pulses (FIGS. 8A and 8F). It may be advantageous to expose a wafer to a reactant of higher (partial) pressure to facilitate surface saturation in a shorter time. As long as the chamber pressures are equalized during purging before vertical movement (FIG. 8B), there is no disturbance to the operation of the apparatus, and problems associated with particle contamination can be avoided.

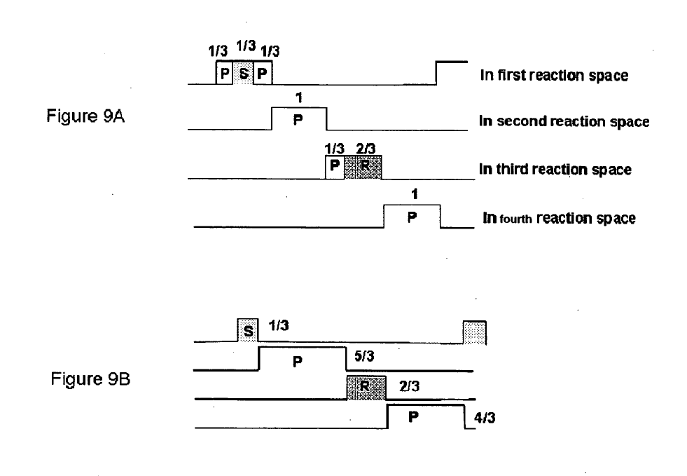

Apparatuses and methods of the preferred embodiments have several advantages over prior art methods. For example, preferred embodiments permit higher flexibility in pulse time combination. With reference to FIG. 9A, according to methods of preferred embodiments, pulses of a metal source gas (“S”), a reactant gas (“R”) and a purge gas (“P”) can have varying durations despite the various wafers having identical wafer residence times in their respective reaction spaces in a given cycle. Pulse durations are referenced in relation to a common wafer residence time of “1” (also referred to herein as “full residence time”). A wafer is processed sequentially in four reaction spaces or chambers of the multi-wafer ALD apparatus. In the first reaction space the purge gas is pulsed for the first ⅓ of a residence time, the source gas for the second ⅓ of a residence time, and the purge gas again for the last ⅓ of a residence time. Next, the wafer is moved to the second reaction space and the purge gas is pulsed for a full residence time (“1”), subsequent to which pulse the wafer is moved to the third reaction space. In the third reaction space the purge gas is pulsed for the first ⅓ of a residence time and the reactant gas is pulsed for the last ⅔ of a residence time. Next, the wafer is moved to the fourth reaction space, and the purge gas is pulsed for a full residence time. Now the wafer has completed one ALD cycle. The cycle may be repeated as desired until a film of predetermined thickness is formed over the wafer.

With reference to FIG. 9B, the ALD cycle of FIG. 9A is represented from the viewpoint of the wafer. In the four-reaction space multi-wafer ALD apparatus, any ALD cycle time sequence can be configured such that the source gas and reactant gas pulsing times (⅓ and ⅔, respectively) are shorter than the residence time (unity, as in FIG. 9A) and both of purge gas pulsing times ( 5/3 and 4/3) are longer than the residence time. When no dedicated purge chamber is provided as illustrated in FIGS. 4A, 4B and 7A-7C, there is no intrinsic limitation for ALD cycle time sequence except practical considerations to prevent gas phase mixing of the source gas and the reactant gas.

Methods of preferred embodiments can advantageously minimize time lost for purging by using the wafer transfer time for part of the purging periods. The time to transfer wafers coincides, at least in part, with the purging time. Additionally, preferred embodiments permit processing of several wafers at a time, while permitting a significant increase of wafer throughput in relation to single wafer processing. Further, since the reaction spaces of preferred embodiments are substantially isolated from one another, problems associated with particle generation (and contamination) are significantly reduced, if not eliminated. By purging the reaction spaces and the remainder of the deposition chamber during wafer transfer from one reaction space to another, unwanted deposition on wafer surfaces, in addition to the substrate support structure and other reactor parts external to the reaction spaces, is reduced. Because each reaction space is exposed to only one reactant, film build-up on the walls of each of the reaction spaces is avoided.

In reaction spaces configured for in situ plasma generation, apparatuses and methods of preferred embodiments are advantageous for plasma-enhanced atomic layer deposition (PEALD). At least one of the reaction spaces may include an in situ plasma generator (e.g. showerhead-type plasma generator described above) configured to continuously generate plasma in situ. Preferably during wafer processing, RF power is continuously supplied to the plasma generator and plasma-excited species of a vapor phase species (e.g., H₂) are continuously generated in the reaction space. PEALD may be performed by moving wafers through the reaction space comprising the plasma-excited species as well as other reaction spaces that may not include plasma-excited species. There is no need to switch RF power “on” and “off” several or dozens of times per minute. Thus, concerns associated with long-term stability of the RF power source are eliminated. Additionally, PEALD of metallic films using systems and methods of preferred embodiments is not different from PEALD of dielectric films. In a time-divided PEALD process, build-up of conductive metallic films (e.g., films of elemental metal, metal nitride, metal carbide, and metal boride) in a reaction space is problematic; in such conventional chambers it is difficult to maintain electric isolation of RF electrodes of an in situ plasma generator from one another in the reaction space. However, the time and space co-divided apparatuses of preferred embodiments, by keeping reactants isolated from one another, advantageously eliminate build-up of conductive metallic films in the reaction space.

Although preferred embodiments have been described in the context of ALD, it would be appreciated that apparatuses and methods of preferred embodiments may be configured for CVD. As an example, rather than pulsing one reactant (or source gas) into a reaction space, a plurality of reactants may be pulsed simultaneously, thus permitting growth of films of thin films of several monolayer thickness. Such a system may be suited for CVD if thin films formed on respective wafer (or substrate) surfaces are not self-limiting. Laminated films of different materials may be conveniently deposited using the embodiments of the present invention, which, for example, may be used for an optical filter or a Bragg reflector. As another example, the multi-wafer ALD apparatuses of preferred embodiments may be configured and/or operated to achieve higher deposition rates than what can be achieved solely through self-limiting surface reactions. As long as particle generation is within acceptable levels, shorter purge time(s) (such that, for example, allowing 3% of reactants to remain in a reaction space before moving a wafer) may enable higher throughput.

It would be appreciated that a control system (or controller) may be provided to control various aspects of wafer processing, such as, e.g., reactant pulsing, purge gas pulsing, reactant removal, purge gas removal, by-product removal, movement of the substrate support platform, wafer residence times, pressure in each of the reaction spaces, pumps, substrate temperature and in situ and/or remote plasma generation. The controller may be configured to control plasma generation parameters, which include, without limitation, radio frequency (RF) power on time, RF power amplitude, RF power frequency, reactant concentration, reactant flow rate, reaction space pressure, total gas flow rate, reactant pulse durations and separations, and RF electrode spacing. The controller may comprise one or more computers configured to communicate with each other and various processing units of the apparatuses of preferred embodiments. The controller is also configured to control robot movement for loading and unloading substrates (or wafers) to and from the reaction spaces. The controller is configured to control the switches of each of the reaction spaces (e.g., switches 178, 188, 198 and 208 of FIG. 3).

In at least some of the aforesaid embodiments, any element used in an embodiment can interchangeably be used in another embodiment unless such a replacement is not feasible.

It will be understood by those of skill in the art that numerous and various modifications can be made without departing from the spirit of the present invention. Therefore, it should be clearly understood that the forms of the present invention are illustrative only and are not intended to limit the scope of the present invention. All modifications and changes are intended to fall within the scope of the invention, as defined by the appended claims.

1. A method of forming a film or thin film over a substrate using an atomic layer deposition (ALD) apparatus, comprising:
providing a substrate with a surface exposed to a first reaction space;
contacting the surface with a vapor phase pulse of a first reactant in the first reaction space;
removing the first reactant from the first reaction space;
moving the substrate away from the first reaction space and towards a second reaction space;
exposing the surface of the substrate to the second reaction space; and
contacting the surface with a vapor phase pulse of a second reactant in the second reaction space.

2. The method of claim 1, wherein removing comprises purging the first reaction space.

3. The method of claim 1, further comprising purging the first reaction space while moving the substrate to the second reaction space.

4. The method of claim 1, further comprising purging the second reaction space after contacting the surface with the vapor phase of the second reactant.

5. The method of claim 1, further comprising moving the substrate to the first reaction space after contacting the surface with the vapor phase of the second reactant.

6. The method of claim 1, further comprising moving the substrate to a third reaction space after contacting the surface with the vapor phase of the second reactant.

7. The method of claim 1, wherein the second reaction space is adjacent to the first reaction space.

8. The method of claim 1, wherein moving comprises moving a platform supporting the substrate.

9. The method of claim 8, wherein the platform supports the substrate during contacting.

10. The method of claim 8, wherein moving comprises rotating the platform.

11. The method of claim 10, wherein moving comprises rotating two or more substrates among 2, 4, 6, 8, or 10 reaction spaces, each exposed to at most one reactant in an ALD sequence employing two reactants.

12. The method of claim 10, wherein moving comprises rotating two or more substrates among 3, 6, or 9 reaction spaces, each exposed to at most one reactant in an ALD sequence employing three reactants.

13. The method of claim 10, wherein rotating comprises back-and-forth rotational motion.

14. The method of claim 8, wherein moving further comprises vertically separating the platform from an enclosure partially defining the first reaction space.

15. The method of claim 14, wherein the enclosure comprises a plurality of walls.

16. The method of claim 1, wherein at least one of the first reaction space and second reaction space comprises a showerhead.

17. The method of claim 1, wherein at least one of the first and second reactant is a plasma-excited species.

18. The method of claim 17, wherein the plasma-excited species is generated in the first or second reaction space.

19. The method of claim 17, wherein the plasma-excited species is generated remotely.

20. The method of claim 1, wherein contacting the surface with the vapor phase pulse of the first reactant adsorbs no more than a monolayer of an adsorbed species of the first reactant on the surface, and contacting the surface with the vapor phase pulse of the second reactant comprises reacting the second reactant with the adsorbed species of the first reactant.

21. The method of claim 1, further comprising repeating contacting, removing and moving at least ten times.

22. The method of claim 1, wherein providing the substrate comprises exposing at least a portion of a substrate support platform to the first reaction space.

23. The method of claim 1, providing the substrate comprises forming a seal between a portion of the surface of the substrate and a lower portion of an enclosure that defines the first reaction space.

24. The method of claim 1, providing the substrate comprises forming a seal between a substrate support platform and the lower portion of an enclosure that defines the first reaction space, such that at least a portion of the substrate support platform is exposed to the first reaction space.

25. A multi-wafer ALD apparatus comprising a first reaction space and a second reaction space, and a control system configured to perform the method of claim 1.

26. A method of processing a plurality of wafers using a semi-batch deposition apparatus, the semi-batch deposition apparatus including a plurality of chambers, the method comprising the steps of:
(a) introducing a surface of a first wafer to a first chamber and a surface of a second wafer to a second chamber;
(b) pulsing a first vapor phase reactant into the first chamber for a first time period and a second vapor phase reactant into the second chamber for a second time period;
(c) removing the first vapor phase reactant from the first chamber after the first time period and the second vapor phase reactant from the second chamber after the second time period;
(d) moving the first wafer away from the first chamber and the second wafer away from the second chamber;
(e) moving the first wafer towards the second chamber to introduce the surface of the first wafer to the second chamber; and
(f) pulsing the second vapor phase reactant into the second chamber for a third time period.

27. The method of claim 26, wherein the first time period is not equal to the second time period.

28. The method of claim 26, wherein the first chamber is adjacent to the second chamber.

29. The method of claim 26, wherein the second chamber is adjacent to a third chamber.

30. The method of claim 29, wherein step (a) further comprises introducing a surface of a third wafer to the third chamber and a surface of a fourth wafer to a fourth chamber.

31. The method of claim 30, wherein step (e) further comprises moving the third wafer to the fourth chamber and the fourth wafer to the first chamber.

32. The method of claim 26, further comprising purging the first chamber and the second chamber while moving the first wafer towards the second chamber.

33. The method of claim 26, wherein moving the first wafer away from the first chamber and the second wafer away from the second chamber comprises vertically moving the first wafer away from the first chamber and rotating a platform supporting the first and second wafers.

34. The method of claim 26, wherein an area below the first and second reaction spaces is purged.

35. The method of claim 26, wherein step (e) further comprises moving the second wafer towards a third chamber to introduce the surface of the second wafer to the third chamber.

36. The method of claim 26, further comprising moving the first wafer towards a third chamber and the second wafer towards a fourth chamber after step (f).

37. The method of claim 26, further comprising moving the first wafer towards the first chamber and the second wafer towards the second chamber after step (f).

38. The method of claim 26, wherein removing comprises purging.

39. The method of claim 26, wherein moving the first wafer away from the first chamber and the second wafer away from the second chamber comprises purging a space above a platform and below a cover defining the chambers.

40. The method of claim 39, further comprising purging a gap between an edge of the platform and a wall laterally disposed in relation to the platform.

41. The method of claim 26, wherein moving the first wafer away from the first chamber and the second wafer away from the second chamber further comprises purging each of the chambers through passages disposed in a cover defining the chambers.

42. The method of claim 26, wherein introducing comprises sealing an opening of each of the first and second chambers.

43. The method of claim 42, wherein the first chamber has a first pressure and the second chamber has a second pressure, and the first and second pressures are independently controllable during pulsing.

44. A method of processing a wafer using a deposition apparatus, comprising:
providing a plurality of spatially-separated reaction zones including a first reaction zone and a second reaction zone;
repeatedly moving a wafer between the first reaction zone and the second reaction zone;
repeatedly and alternately pulsing and removing a first reactant vapor in the first reaction zone; and
repeatedly and alternately pulsing and removing a second reactant vapor in the second reaction zone.

45. The method of claim 44, wherein removing comprises purging at least one of the reaction zones before moving.

46. The method of claim 45, further comprising purging each of the reaction zones while moving.

47. The method of claim 44, wherein repeatedly moving comprises rotating a wafer support platform.

48. The method of claim 47, wherein the wafer support platform supports between 2 and 10 wafers and underlies a corresponding number of reaction zones.

49. The method of claim 44, wherein a pulsing duration of at least one of the first reactant and second reactant pulsing in the first and second reaction zones is shorter than a wafer residence time in each reaction zone.

50. The method of claim 44, further comprising repeatedly moving a second wafer between a third reaction zone and a fourth reaction zone.

51. The method of claim 44, wherein repeatedly moving the wafer between the first reaction zone and the second reaction zone comprises moving the wafer repeatedly to a third reaction zone.

52. The method of claim 51, wherein the third reaction zone is configured to flow a purge gas only.

53. The method of claim 51, further comprising repeatedly and alternately pulsing and removing a third reactant vapor in the third reaction zone.

54.-79. (canceled)

80. A vapor phase deposition apparatus, comprising:
a plurality of spatially-separated reaction zones including a first reaction zone and a second reaction zone, each of the reaction zones communicating with a gas source, each of the reaction zones comprising an axis perpendicular to an opening in each of the reaction zones, each opening configured to accept a surface of a substrate;
a substrate support platform configured to move a plurality of substrates among the reaction zones during deposition; and
a control system configured to control movement of the substrate support platform and to pulse a first reaction gas into the first reaction zone and a second reaction gas into the second reaction zone, with at most one reaction gas pulsed in each reaction zone.

81. The apparatus of claim 80, wherein the control system is further configured to pulse purge gas into the reaction zones.

82. The apparatus of claim 81, wherein the control system is configured to simultaneously pulse purge gas into the reaction zones and move the substrate support platform.

83. The apparatus of claim 80, wherein adjacent reaction zones communicate with a different gas source.

84. The apparatus of claim 80, wherein the substrate support platform is configured to move the substrates vertically along an axis parallel to the axis of each of the reaction zones.

85. The apparatus of claim 80, wherein the substrate support platform is configured to move the substrates laterally from below the openings of each of the reaction zones.

86. The apparatus of claim 80, wherein the substrate support is configured to rotate about an axis parallel to the axis of the first reaction zone.

87. The apparatus of claim 80, wherein the control system is configured to repeatedly alternate between pulsing the first reaction gas and pulsing a purge gas in the first reaction zone.

88. The apparatus of claim 80, wherein the control system is configured to repeatedly alternate between pulsing the second reaction gas and pulsing a purge gas in the second reaction zone.

89. The apparatus of claim 80, wherein the first reaction zone is separated from the second reaction zone by at least one wall.

90. The apparatus of claim 89, wherein the at least one wall comprises gas flow passages configured to direct purge gas to an area between a cover and the substrate support platform, wherein the cover defines the reaction zones together with the substrate support platform.

91. The apparatus of claim 80, wherein the openings in each of the reaction zones are sealable by surfaces of the substrate support platform surrounding a substrate position.

92. The apparatus of claim 80, wherein the openings in each of the reaction zones are sealable by substrate surfaces.

93. The apparatus of claim 80, wherein the substrate support platform is configured to support 2-10 substrates and the apparatus comprises a corresponding number of reaction zones.

94. A multi-wafer atomic layer deposition (ALD) apparatus, comprising:
a plurality of walls defining at least a first reaction space and a second reaction space, the first reaction space and second reaction space separated by at least one separating wall, wherein the at least one separating wall comprises a gas flow passage communicating with a source of purge gas; and
a platform configured to support at least two substrates, the platform configured to move substrates vertically and laterally between the first reaction space and the second reaction space.

95. The apparatus of claim 94, wherein the at least one separating wall is hollow.

96. The apparatus of claim 94, wherein the first reaction space comprises a gas flow passage configured to direct a reactant gas into the first reaction space.

97. The apparatus of claim 94, wherein the first reaction space comprises an exit passage configured for gas removal.

98. The apparatus of claim 94, wherein the platform is configured to rotate about a central axis.

99. The apparatus of claim 94, wherein each of the reaction spaces comprises an opening configured to accept a surface of a substrate supported on the platform.

100. The apparatus of claim 99, wherein surfaces of the platform surrounding each substrate position are configured to seal one or more of the openings.

101. The apparatus of claim 99, wherein substrate surfaces are configured to seal one or more of the openings.

102. The apparatus of claim 94, further comprising a control system configured to pulse reactant gases into each of the first and second reaction spaces.

103. The apparatus of claim 102, wherein the control system is configured to direct purge gas through the gas flow passage to a space between the platform and the plurality of walls when they are vertically separated.

104. The apparatus of claim 102, wherein the control system is configured to direct purge gas through a space below the cover and between the platform and a wall laterally disposed in relation to the platform.

105. The apparatus of claim 94, wherein the platform is configured to move the substrate laterally via back-and-forth rotational motion.
